(19) United States
(12) Patent Application Publication
(10) Pub. No.: US 2024/0292699 A1
(43) Pub. Date: Aug. 29, 2024

(54) DISPLAY DEVICE

(71) Applicant: Samsung Display Co., LTD., Yongin-si (KR)

(72) Inventors: Dong Woo KIM, Yongin-si (KR); Kwi Hyun KIM, Yongin-si (KR); Se Hyun LEE, Yongin-si (KR); Won Jun LEE, Yongin-si (KR)

(21) Appl. No.: 18/509,141

(22) Filed: Nov. 14, 2023

(30) Foreign Application Priority Data
Feb. 23, 2023 (KR) 10-2023-0024413

(51) Int. Cl. H10K 59/35; G06F 3/01; H10K 59/60

(52) U.S. Cl. CPC H10K 59/353; G06F 3/013; H10K 59/352; H10K 59/60; H10K 59/38

(57) ABSTRACT

A display device includes: a glasses corresponding to a display area of a lens; a display panel configured to display light; a reflective member configured to reflect the display light emitted from the display panel in a direction of the glasses; and a light source unit configured to emit near-infrared light for tracking eyes of a user, wherein the display panel includes a plurality of pixel groups arranged in a matrix configuration, the pixel groups including a red pixel, a green pixel, a blue pixel and a sensor pixel including a photodiode configured to sense the near-infrared light reflected by the eyes of the user, one pixel group includes 2*2 sub-areas, and any one of the red pixel, the green pixel, and composite pixels, in which the blue pixel and the sensor pixel are adjacent to each other, is located in each of the sub-areas.

### CROSS-REFERENCE TO RELATED APPLICATIONS

The present application claims priority to and benefits of Korean Patent Application No. 10-2023-0024413 filed on Feb. 23, 2023, in the Korean Intellectual Property Office, the entire contents of which is incorporated herein by reference.

### BACKGROUND

### 1. Field

Aspects of some embodiments of the present disclosure relate to a display device.

### 2. Description of Related Art

A wearable device has been developed in the form of glasses or a helmet so that a focus is formed at a distance close to a user's eyes. For example, the wearable device may be a head mounted display (HMD) device or an AR glasses. The wearable device may provide users with an augmented reality (AR) screen or a virtual reality (VR) screen.

The wearable device such as the HMD device or the AR glasses may desirably have a display specification of a minimum 2000 PPI (the number of pixels per inch) to allow users to use it for a long time without dizziness. To this end, an organic light emitting diode on silicon (OLEDoS) technology, which is related to a high-resolution compact organic light emitting display device, has emerged. The OLEDOS technology is the technology for arranging an organic light emitting diode (OLED) on a semiconductor wafer substrate on which a complementary metal oxide semiconductor (CMOS) is located.

The wearable device may track movement of a user's eyes and vary resolution of a screen based on the tracked movement of the user's eyes when displaying an AR screen or a VR screen. For example, the wearable device may detect a direction of the user's gaze, and determine a central vision area corresponding to the gaze and a peripheral vision area except the central vision area. A foveated rendering technology for displaying a high-resolution screen on the central vision area and displaying a low-resolution screen on the peripheral vision area may be applied to the wearable device. The wearable device may irradiate near-infrared light having an output wavelength of about 780 nanometers (nm) to about 1400 nm to the user's eyes in order to track the movement of the user's eyes, and may detect the near-infrared light reflected from the user's eyes.

The above information disclosed in this Background section is only for enhancement of understanding of the background and therefore the information discussed in this Background section does not necessarily constitute prior art.

### SUMMARY

Aspects of the present disclosure provide a display device that may prevent screen quality from being deteriorated due to a sensor pixel for sensing reflective light for an eye tracking function.

The characteristics of embodiments of the present disclosure are not limited to those mentioned above and additional objects of the present disclosure, which are not mentioned herein, will be clearly understood by those skilled in the art from the following description of the present disclosure.

According to some embodiments of the present disclosure, a display device may include a glasses corresponding to a display area of a lens, a display panel emitting display light, a reflective member reflecting the display light emitted from the display panel in a direction of the glasses, and a light source unit emitting near-infrared light for tracking a user's eyes. The display panel may include a plurality of pixel groups arranged in the form of a matrix. The pixel groups may include a red pixel, a green pixel, a blue pixel and a sensor pixel including a photodiode configured to sense the near-infrared light reflected by the user's eyes. One pixel group may include 2*2 sub-areas, and any one of the red pixel, the green pixel, and composite pixels, in which the blue pixel and the sensor pixel are arranged to be adjacent to each other, may be in each of the sub-areas.

According to some embodiments, the red pixel and the green pixel may have the same area, and each of the red pixel and the green pixel may have a horizontal and vertical ratio of 1 to 1, and each of the blue pixel and the sensor pixel may have a horizontal and vertical ratio of 1/2 to 2.

According to some embodiments, among the 2*2 sub-areas, a blue pixel in a first row and a blue pixel in a second row may be to be adjacent to each other, and a sensor pixel in the first row and a sensor pixel in the second row may be adjacent to each other.

According to some embodiments, among the 2*2 sub-areas, a blue pixel in a first row and a sensor pixel in a second row may be adjacent to each other, and a sensor pixel in the first row and a blue pixel in the second row may be adjacent to each other.

According to some embodiments, among the 2*2 sub-areas, the composite pixels in which the blue pixel and the sensor pixel are arranged to be adjacent to each other may be in a first row and a first column, and the blue pixel and the sensor pixel may be adjacent to each other in a diagonal direction.

According to some embodiments, the sensor pixel may be positioned at a corner of the pixel group, and the blue pixel may be in a second row and a second column among the 2*2 sub-areas.

According to some embodiments, the blue pixel may be positioned at a corner of the pixel group, and the sensor pixel may be in a second row and a second column among the 2*2 sub-areas.

According to some embodiments of the present disclosure, a display device may include a glasses corresponding to a display area of a lens, a display panel emitting display light, a reflective member reflecting the display light emitted from the display panel in a direction of the glasses, and a light source unit emitting near-infrared light for tracking a user's eyes. The display panel may include a plurality of pixel groups arranged in the form of a matrix. The pixel groups may include a red pixel, a green pixel, a blue pixel and a sensor pixel including a photodiode configured to sense the near-infrared light reflected by the user's eyes. One pixel group may include 4*4 sub-areas, and any one of the red pixel, the green pixel, the blue pixel and the sensor pixel may be in each of the sub-areas.

According to some embodiments, the sensor pixel may be in a sub-area positioned at any one corner of the 4*4 sub-areas, and any one of the red pixel, the green pixel, and the blue pixel may be in the other sub-areas except the sub-area positioned at any one corner.

According to some embodiments, among the 4*4 sub-areas, the red pixel and the green pixel may be in a first column and a third column, in the first column and the third column, the red pixel and the green pixel may be alternately arranged, and the blue pixel may be in a second column and a portion of a fourth column except the sensor pixel.

According to some embodiments, the plurality of pixel groups include a first pixel group and a second pixel group, and the first pixel group and the second pixel group may be arranged in accordance with a designated rule, among the 4*4 sub-areas of the first pixel group, the red pixel and the green pixel may be alternately in a first column and a third column, the blue pixel may be in a second column and a portion of a fourth column except the sensor pixel, and the sensor pixel may be in the first row and the fourth column, and among the 4*4 sub-areas of the second pixel group, the red pixel and the green pixel may be alternately arranged in the first column and the third column, the blue pixel may be in the second column and a portion of the fourth column except the sensor pixel, and the sensor pixel may be in a fourth row and the fourth column.

According to some embodiments, resolution of the first pixel group and resolution of the second pixel group may be the same as each other in the display panel.

According to some embodiments, the plurality of pixel groups include a first pixel group and a second pixel group, and the first pixel group and the second pixel group may be arranged in accordance with a designated rule, among the 4*4 sub-areas of the first pixel group, composite pixels in which the blue pixel and the sensor pixel are adjacent to each other in a diagonal direction may be in four sub-areas adjacent to a center of the first pixel group, and the second pixel group does not include the sensor pixel.

According to some embodiments, among the 4*4 sub-areas of the first pixel group, the composite pixels may be in a second row and a second column, the second row and a third column, a third row and the second column, and the third row and the third column, and the blue pixel and the sensor pixel may be arranged such that the composite pixels may be symmetrical based on the center of the first pixel group.

According to some embodiments, the sensor pixel in the first pixel group may be closer to the center of the first pixel group than the blue pixel, so that a combination of adjacent sensor pixels has a rhombus shape as a whole.

According to some embodiments, resolution of the first pixel group and resolution of the second pixel group may be the same as each other in the display panel.

According to some embodiments, the first pixel group and the second pixel group may be alternately arranged.

According to some embodiments, the first pixel group may surround the outside of the display panel, and the second pixel group may be inside the display panel.

According to some embodiments, the first pixel group may be only in four corner areas of the display panel, and the second pixel group may be in the other area except the four corner areas.

According to some embodiments, the display panel may include a semiconductor wafer substrate and an OLED on the semiconductor wafer substrate.

According to some embodiments, the display device according to the embodiments may optimize arrangement of a sensor pixel for sensing reflective light for an eye tracking function, thereby preventing or reducing screen quality deterioration due to the sensor pixel.

The characteristics of embodiments of the present disclosure are not limited to those mentioned above and more various effects are included in the following description of the present disclosure.

### BRIEF DESCRIPTION OF THE DRAWINGS

The above and other characteristics and features of some embodiments according to the present disclosure will become more apparent by describing in more detail aspects of some embodiments thereof with reference to the attached drawings, in which:

FIG. 1 is a front view illustrating a wearable device including a display device according to some embodiments;

FIG. 2 is a rear view illustrating the wearable device shown in FIG. 1 according to some embodiments;

FIG. 3 is a view illustrating another example of a wearable device including a display device according to some embodiments;

FIG. 4 is a schematic block view illustrating a display device according to some embodiments;

FIG. 5 is a schematic view illustrating a display module according to some embodiments;

FIG. 6 is a plan view illustrating a display panel according to some embodiments;

FIG. 7 is a cross-sectional view illustrating a light emission area of a display panel according to some embodiments;

FIG. 8 is a cross-sectional view illustrating a sensor pixel of a display panel according to some embodiments;

FIG. 9 is a plan view illustrating arrangement of a sensor pixel included in a pixel group according to some embodiments;

FIG. 10 is a plan view illustrating arrangement of a sensor pixel included in a pixel group according to some embodiments;

FIG. 11 is a plan view illustrating arrangement of a sensor pixel included in a pixel group according to some embodiments;

FIG. 12 is a plan view illustrating arrangement of a sensor pixel included in a pixel group according to some embodiments;

FIG. 13 is a plan view illustrating arrangement of a sensor pixel included in a pixel group according to some embodiments;

FIG. 14 is a plan view illustrating arrangement of a sensor pixel included in a pixel group according to some embodiments;

FIG. 15 is a plan view illustrating arrangement of a sensor pixel included in a pixel group according to some embodiments;

FIG. 16 is a plan view illustrating arrangement of a sensor pixel included in a pixel group according to some embodiments;

FIG. 17 is a plan view illustrating arrangement of a sensor pixel included in a pixel group according to some embodiments; and

FIG. 18 is a plan view illustrating arrangement of a sensor pixel included in a pixel group according to some embodiments.

### DETAILED DESCRIPTION

Aspects of some embodiments of the present invention will now be described more fully hereinafter with reference to the accompanying drawings, in which aspects of some embodiments of the invention are shown. This invention may, however, be embodied in different forms and should not be construed as limited to the embodiments set forth herein. Rather, these embodiments are provided so that this disclosure will be thorough and complete, and will filly convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present invention. Similarly, the second element could also be termed the first element.

Features of each of various embodiments of the present disclosure may be partially or entirely combined with each other and may technically variously interwork with each other, and respective embodiments may be implemented independently of each other or may be implemented together in association with each other.

Hereinafter, aspects of some embodiments will be described in more detail with reference to the accompanying drawings.

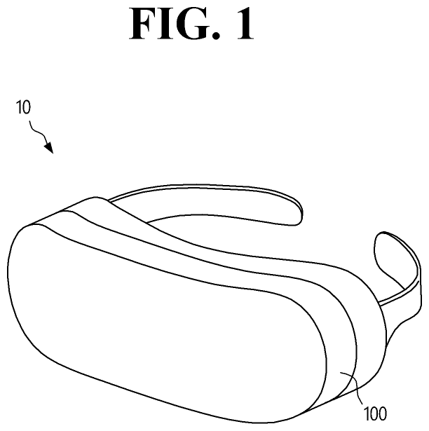

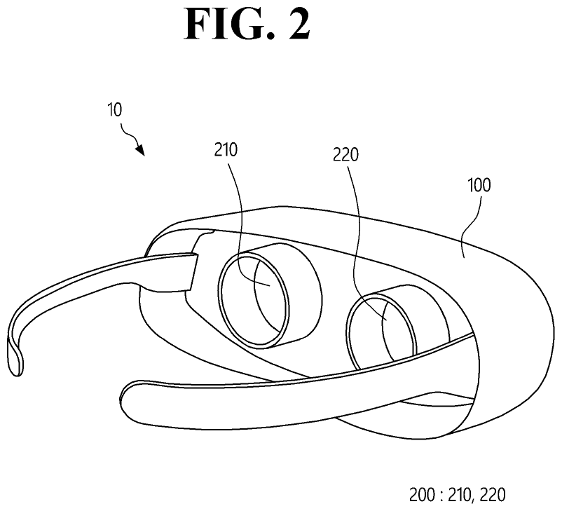

FIG. 1 is a front view illustrating a wearable device 100 including a display device 10 according to some embodiments. FIG. 2 is a rear view illustrating the wearable device 100 shown in FIG. 1.

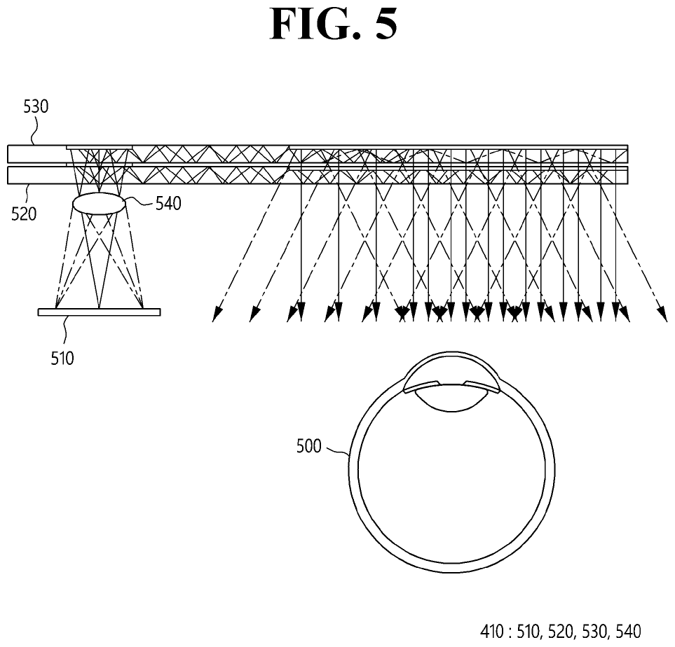

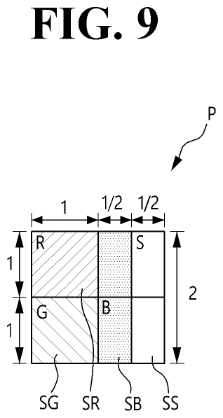

Referring to FIGS. 1 and 2, the display device 10 according to some embodiments may be a display device included in an HMD device. In the HMD device, the display device 10 may be located inside a main body, and a lens 200 for displaying a screen may be located on a rear surface of the main body. The lens 200 may include a left-eye lens 210 corresponding to a left-eye of a user and a right-eye lens 220 corresponding to a right-eye of the user. Each of the left-eye lens 210 and the right-eye lens 220 may include a glasses for displaying a screen output from the display device 10. A method for displaying the screen through the glasses by the display device 10 will be described later in more detail with reference to FIGS. 5 and 9.

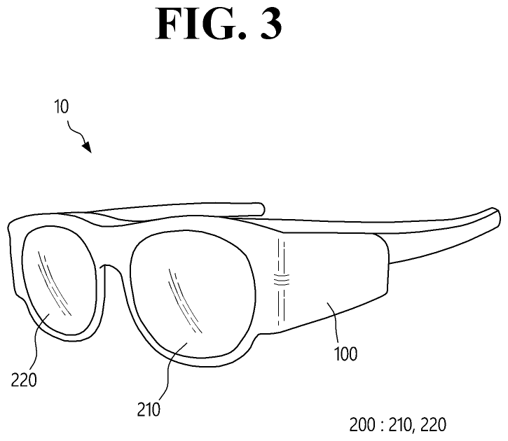

FIG. 3 is a view illustrating another example of the wearable device 10 including the display device 10 according to some embodiments.

Referring to FIG. 3, the display device 10 according to some embodiments

may be a display device included in AR glasses. The AR glasses may have an eyeglasses shape, and may include a see-through (or transparent or translucent) lens. The see-through lens may include a left-eye lens 210 corresponding to a left-eye of a user and a right-eye lens 220 corresponding to a right-eye of the user. Each of the left-eye lens 210 and the right-eye lens 220 may include glasses for displaying the screen output from the display device 10. A method for displaying the screen through the glasses by the display device 10 will be described later in more detail with reference to FIGS. 5 and 9.

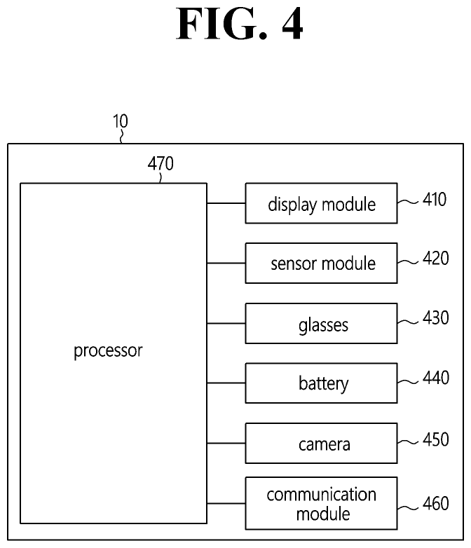

FIG. 4 is a schematic block view illustrating a display device 10 according to some embodiments. FIG. 5 is a schematic view illustrating a display module according to some embodiments. For example, FIG. 5 illustrates an optical path through which display light output from a display panel 510 of the display device 10 moves.

The display device 10 shown in FIGS. 4 and 5 may be applied to the HMD device shown in FIGS. 1 and 2 or the AR glasses shown in FIG. 3.

Referring to FIGS. 4 and 5, the display device 10 according to some embodiments may include a processor 470, a display module 410, a sensor module 420, a glasses 430, a battery 440, a camera 450, and a communication module 460. According to some embodiments, the display device 10 may further include other elements described in the present disclosure. The display device 10 may omit at least some elements shown in FIG. 4.

The processor 470 executes command languages stored in a memory to control operations of the elements (e.g., the display module 410, the sensor module 420, the battery 440, the camera 450, and the communication module 460) of the display device 10. The processor 470 may be electrically and/or operatively connected to the display module 410, the sensor module 420, the battery 440, the camera 450, and the communication module 460. The processor 470 may execute software to control at least one other element (e.g., the display module 410, the sensor module 420, the battery 440, the camera 450, and the communication module 460) connected to the processor 470. The processor 470 may acquire a command from the elements included in the display device 10, interpret the acquired command, and process and/or compute various data in accordance with the interpreted command.

The display device 10 may receive the data processed through a processor 120 embedded in an external device (e.g., a smartphone or a tablet PC) from the external device. For example, the display device 10 may photograph an object (e.g., a real object or user's eyes) through the camera 450, and may transmit the photographed image to the external device through the communication module 460. The display device 10 may receive the data based on the image photographed by the display device 10 from the external device. The external device may generate image data related to augmented reality based on information (e.g., shape, color, or position) of the photographed object received from the display device 10, and may transmit the image data to the display device 10. The display device 10 may request additional information based on an image obtained by photographing an object (e.g., a real object or user's eyes) through the camera 450 to the external device, and may receive additional information from the external device.

The display module 410 may include a display panel (e.g., the display panel 510 of FIG. 5) and a light transfer member (e.g., waveguides 520 and 530) for transferring light emitted from the display panel 510 to a portion of the glasses 430. In the present disclosure, the display panel 510 may refer to a light source unit for generating display light input to the waveguides (e.g., 520 and 530 of FIG. 5). The display panel 510 may be a display panel to which an organic light emitting diode on silicon (OLEDoS) technology is applied. For example, the display panel may include an OLED located on a semiconductor wafer substrate on which a complementary metal oxide semiconductor (CMOS) is located.

The display panel 510 of the display module 410 may emit display light for displaying an augmented reality image (or a virtual reality image) based on the control of the processor 470. For example, the display light emitted from the display panel 510 may be transferred a display area of the lens (200 of FIG. 2 or 200 of FIG. 3) through the waveguides 520 and 530 so that the user may see the display light. The display device 10 (e.g., the processor 470) may control the display panel 510 in response to the user's input. Types of the user's input may include a button input, a touch input, a voice input, and/or a gesture input, and may include various input methods capable of controlling an operation of the display panel 510 without being limited thereto.

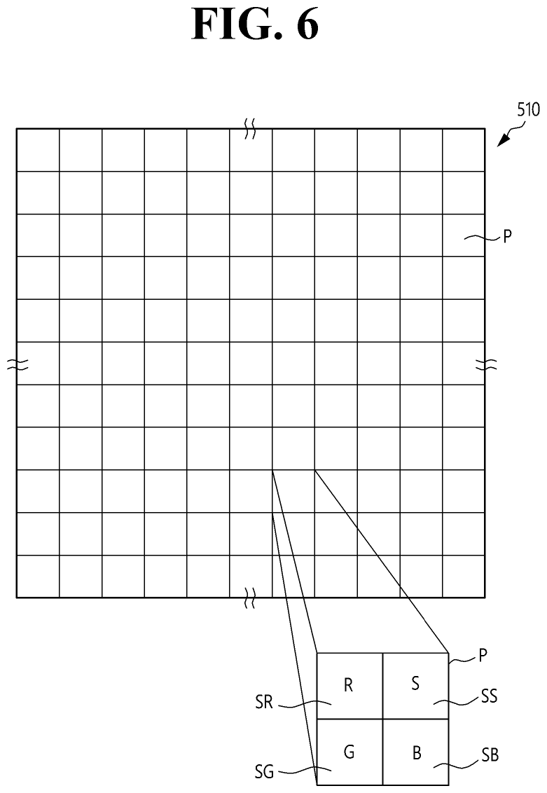

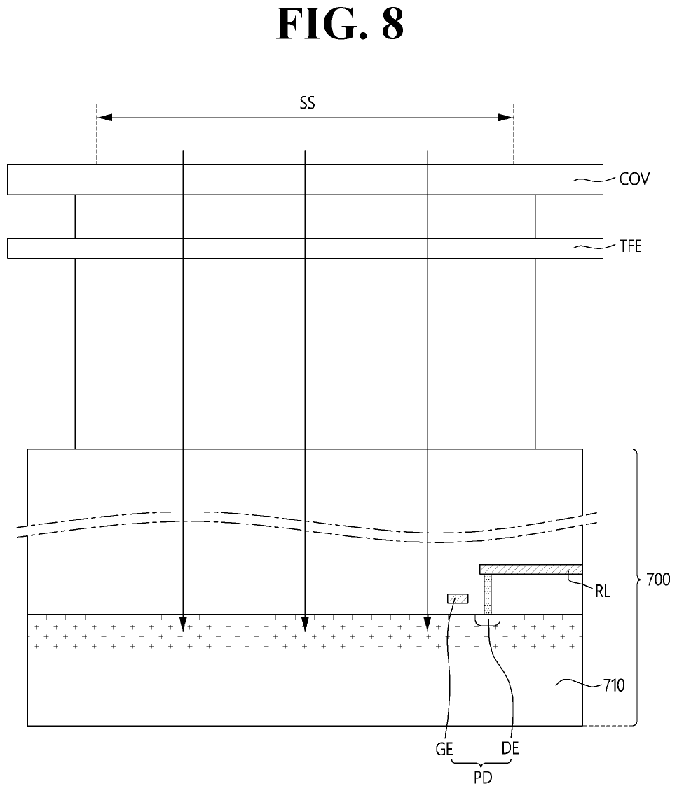

The display device 10 may further include a light source unit to track movement of the user's eye 500. The light source unit may be configured to emit light different from the display light emitted by the display panel 510. The light source unit may be configured to irradiate near-infrared light having an output wavelength of about 780 nm to about 1400 nm to the user's eye. The near-infrared light emitted from the light source unit may be reflected from the user's eye 500, and the reflected near-infrared light may be input to the display panel 510. The display panel 510 is an optical sensor for receiving near-infrared light reflected from the user's eye 500 and tracking movement of the user's eye 500 by using the received near-infrared light, and may include a gaze tracking sensor (for example, sensor pixel SS of FIG. 6). In this case, the gaze tracking sensor may include a photodiode (PD of FIG. 8) located in a sensor pixel of the display panel 510.

When displaying an AR screen or a VR screen, the display device 10 tracks the movement of the user's eyes by using the photodiode (PD of FIG. 8) and varies resolution of a screen based on the tracked movement of the user's eyes. For example, the display device 10 detects a direction of the user's gaze and determines a central vision area corresponding to the gaze and a peripheral vision area except the central vision area. A foveated rendering technology for displaying a high-resolution screen on the central vision area and displaying a low-resolution screen on the peripheral vision area may be applied to the display device 10.

The glasses 430 may be arranged to correspond to the display area of the lens (200 of FIG. 2 or 200 of FIG. 3) of the wearable device. For example, the glasses 430 may be included in each of the left-eye lens (210 of FIG. 1 or 210 of FIG. 3) and the right-eye lens (220 of FIG. 1 or 220 of FIG. 3).

The glasses 430 may include waveguides 520 and 530, and the waveguides 520 and 530 may include at least one of a display waveguide 520 or a gaze tracking waveguide 530.

The display waveguide (e.g., first waveguide) 520 may form a path of light by inducing light such that the display light emitted from the display panel 510 is emitted to the display area of the lens (200 of FIG. 2 or 200 of FIG. 3). For example, the display area of the lens (200 of FIG. 2 or 200 of FIG. 3) may be an area to which light propagating inside the display waveguide 520 is emitted.

The display waveguide 520 may include at least one of at least one diffractive element or a reflective element (e.g., a reflective mirror). The display waveguide 520 may induce the display light emitted from the display panel 510 to the user's eye 500 by using at least one diffractive element or the reflective element, which is included in the display waveguide 520. For example, the diffractive element may include input/output grating, and the reflective element may include total internal reflection (TIR). An optical material (e.g., glass) may be processed in the form of a wafer, so that the optical material may be used as the display waveguide 520, and a refractive index of the display waveguide 520 may vary from about 1.5 to about 1.9.

The display waveguide 520 may include a material (e.g., glass or plastic) capable of totally reflecting the display light in order to induce the display light to the user's eye 500. The material of the display waveguide 520 may not be limited to the aforementioned examples.

The display waveguide 520 may split the display light emitted from the display panel 510 in accordance with a wavelength (e.g., blue, green, or red) to move to a separate path in the display waveguide 520, respectively.

The display waveguide 520 may be located in a portion of the glasses 430. For example, the display waveguide 520 may be located on an upper end of the glasses 430 based on a virtual axis in which a center point of the glasses 430 and a center point of the user's eye 500 are matched with each other and a virtual line orthogonal to the virtual axis at the center point of the glasses 430. The area in which the display waveguide 520 is located may not be limited to the above-described area of the glasses 430, and the area in which the display waveguide 520 is located may be located in any one of the areas of the glasses 430 such that the amount of light reflected in the user's eye 500 is greater than or equal to a reference value.

The sensor module 420 may include at least one sensor (e.g., a gaze tracking sensor and/or an illuminance sensor). The at least one sensor may not be limited to the above-described example. For example, the at least one sensor may further include a proximity sensor or a contact sensor, which is capable of sensing whether the user has worn the display device 10. The display device 10 may sense whether the user wears the display device 10, through the proximity sensor or the contact sensor. When sensing that the user is wearing the display device 10, the display device 10 may be manually and/or automatically paired with another electronic device (e.g., smart phone).

The gaze tracking sensor may sense the reflective light reflected from the user's eye 500 based on the control of the processor 470. The display device 10 may convert the reflective light sensed through the gaze tracking sensor into an electrical signal. The display device 10 may acquire the user's eyeball image through the converted electric signal. The display device 10 may track the user's gaze by using the acquired eyeball image of the user.

The illuminance sensor may sense illuminance (or brightness) near the display device 10, the amount of the display light emitted from the display panel, brightness near the user's eye 500, or the amount of the reflective light reflected in the user's eye 500 based on the control of the processor 470.

The display device 10 may sense illuminance (or brightness) near the user by using the illuminance sensor. The display device 10 may adjust the amount of light (or brightness) of a display (e.g., the display panel 510) based on the sensed illuminance (or brightness).

The gaze tracking waveguide (e.g., the second waveguide) 530 may form a path of light by inducing light such that the reflective light reflected from the user's eye 500 is input to the sensor module 420. The gaze tracking waveguide 530 may be used to transfer the reflective light to the gaze tracking sensor. The gaze tracking waveguide 530 may be formed as an element the same as or different from the display waveguide 520.

The gaze tracking waveguide 530 may be located in a portion of the glasses 430. For example, based on a virtual axis, in which the center point of the glasses 430 and the center point of the user's eye 500 are matched with each other, and a virtual line orthogonal to the virtual line at the central point of the glasses 430, the gaze tracking waveguide 530 may be located on a lower end of the glasses 430. An area in which the gaze tracking waveguide 530 is located may not be limited to the above-described area of the glasses 430, and may be located in any one of the areas of the glasses 430.

The battery 440 may supply power to at least one element of the display device 10. The battery 440 may be charged by being connected to an external power source in a wired or wireless manner. The camera 450 may photograph an image near the display device 10. For example, the camera 450 may photograph an image of the user's eye 500 or photograph a real object image outside the display device 10.

The communication module 460 may include a wired interface or a wireless interface. The communication module 460 may support direct communication (e.g., wired communication) or indirect communication (e.g., wireless communication) between the display device 10 and the external device (e.g., smartphone, or tablet PC).

The communication module 460 may include a wireless communication module (e.g., a cellular communication module, a short-range wireless communication module, or a global navigation satellite system (GNSS) communication module) or a wired communication module (e.g., a local area network (LAN) communication module or a power line communication module).

The wireless communication module may support a 5G network after a 4G network and a next generation communication technology, for example, a new radio (NR) access technology. The NR access technology may support high-speed data transmission of high-capacity data (enhanced mobile broadband (eMBB)), minimization of terminal power, massive machine type communications (mMTC), or ultra-reliable and low-latency communications (URLLC). The wireless communication module 192 may support, for example, a high frequency band (e.g., mmWave band) for achieving a high data transmission rate.

The wireless communication module may include a short-range wireless communication module. The short-range communication may include at least one of wireless fidelity (WiFi), Bluetooth, Bluetooth low energy (BLE), Zigbee, near field communication (NFC), magnetic secure transmission, radio frequency (RF), or body area network (BAN).

Referring to FIG. 5, the display module 410 includes a display panel 510 for outputting display light, waveguides 520 and 530, and a projection lens 540.

The projection lens 540 may be configured to input light emitted from the display panel 510 into the waveguides 520 and 530. In FIG. 5, a portion of light flux emitted from the display panel 510 is input to the waveguides 520 and 530 through the projection lens 540.

The waveguides 520 and 530 may have a plate shape. The waveguides 520 and 530 may include grating that performs a diffraction function, such as diffraction optical elements (DOE) or holographic optical elements (HOE), in a partial area of the plate. A period, depth or refractive index of the grating of the waveguides 520 and 530 may be varied based on conditions such as an output image viewing angle or a refractive index of a plate medium. The waveguides 520 and 530 may distribute an optical signal so that a portion of the optical signal (i.e., display light) input from the display panel 510 is transferred into the waveguide 530 and another portion of the optical signal is output to the outside of the waveguides 520 and 530.

In FIG. 5, the diffraction optical element has been described as an example of the waveguides 520 and 530, but the waveguide may be replaced with a reflective optical element such as a beamsplitter.

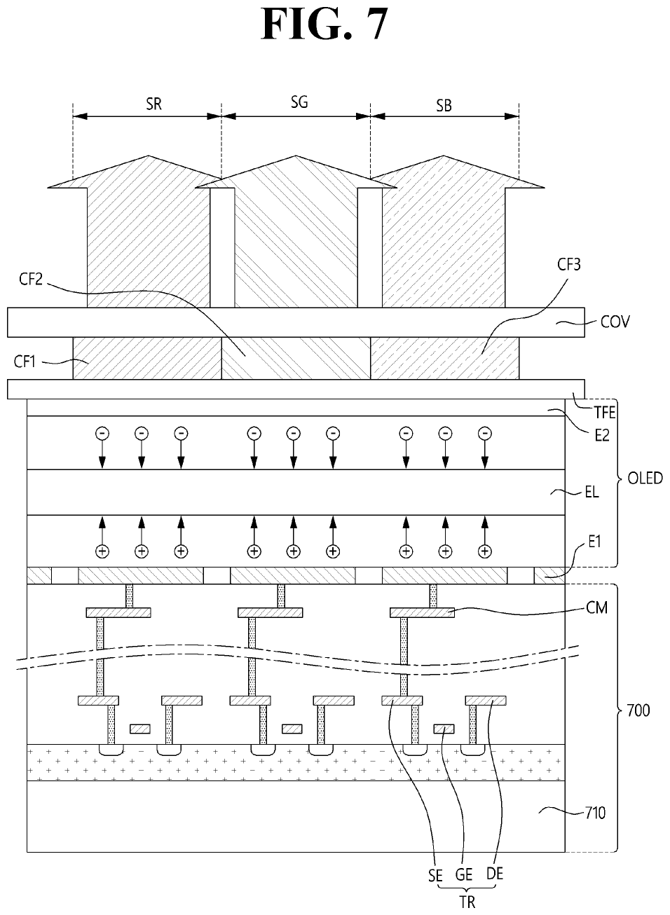

FIG. 6 is a plan view illustrating a display panel 510 according to some embodiments. FIG. 7 is a cross-sectional view illustrating a light emission area of a display panel 510 according to some embodiments. FIG. 8 is a cross-sectional view illustrating a sensor pixel SS of a display panel 510 according to some embodiments.

Referring to FIG. 6, the display panel 510 according to some embodiments may include a plurality of pixel groups P. The plurality of pixel groups P may be arranged in the form of a matrix on a plane of the display panel 510. For example, the display panel 510 may include m*n pixel groups P (e.g., unit pixels). In this case, each of m and n may be an integer greater than 1. Throughout the present disclosure, the sign or symbol * denotes a multiplication code.

Each of the plurality of pixel groups P may be divided into i*i sub-areas, and a red pixel SR, a green pixel SG, a blue pixel SB, and a sensor pixel SS may be located in the sub-areas one by one. In this case, i may be an integer greater than 1. For example, one pixel group P includes 2*2 sub-areas, and any one of the red pixel SR, the green pixel SG, the blue pixel SB and the sensor pixel SS may be located in each of the sub-areas. The red pixel SR, the green pixel SG, the blue pixel SB, and the sensor pixel SS may have substantially the same area. Also, each of the red pixel SR, the green pixel SG, the blue pixel SB and the sensor pixel SS may have a horizontal and vertical ratio of 1 to 1. In the embodiments illustrated with respect to FIG. 6, sensing performance may be increased, and sharpness of an image may be improved in comparison with a comparative example in which one of the red pixel SR, the green pixel SG and the blue pixel SB, and a photodiode PD are located in each of all the sub-areas. That is, in the comparative example, a dot-type photodiode PD may be located on a portion of each of the red pixel SR, the green pixel SG, and the blue pixel SB, but a dot-type stain may be detected on the screen when the display panel 510 is driven.

On the other hand, according to the embodiments illustrated with respect to FIG. 6, the sensor pixel SS is located separately from the red pixel SR, the green pixel SG and the blue pixel SB, which display an image, whereby sensing performance may be increased and a dot-type stain may be avoided to improve sharpness of an image.

FIG. 6 illustrates that one pixel group P includes one red pixel SR, one green pixel SG, one blue pixel SB, and one sensor pixel SS, but various modifications and designs may be made in the arrangement of pixels included in each pixel group P.

The red pixel SR includes a red color filter CF1, and is configured to emit red light as the red color filter CF1 transmits the red light. According to some embodiments, the red pixel SR may be configured so that an emission layer EL directly emits red light, and in this case, the red color filter CF1 may be omitted.

The green pixel SG includes a green color filter CF2, and is configured to emit green light as the green color filter CF2 transmits green light. According to some embodiments, the green pixel SG may be configured so that the emission layer EL directly emits green light, and in this case, the green color filter CF2 may be omitted.

The blue pixel SB includes a blue color filter CF3, and is configured to emit blue light as the blue color filter CF3 transmits blue light. According to some embodiments, the blue pixel SB may be configured so that the emission layer EL directly emits blue light, and in this case, the blue color filter CF3 may be omitted.

The sensor pixel SS includes a photodiode PD, and may sense reflective light reflected from the user's eye 500. The photodiode PD may convert the sensed reflective light into an electrical signal and supply the converted electrical signal to the sensor module 420.

Referring to FIG. 7, the display panel 510 may include a semiconductor wafer substrate 700, an OLED located on the semiconductor wafer substrate 700, and color filters CF1, CF2 and CF3 located on the OLED. A thin-film encapsulation layer TFE covering the emission layer EL of the OLED may be located between the OLED and the color filters CF1, CF2 and CF3. A cover window COV may be located on the color filters CF1, CF2 and CF3. The cover window COV may be attached onto the color filters CF1, CF2 and CF3 by a transparent adhesive member such as an optically clear adhesive (OCA) film.

The semiconductor wafer substrate 700 may include a base substrate 710 and a transistor TR located on the base substrate 710.

The base substrate 710 may be a silicon substrate. The base substrate 710 may be a semiconductor pattern formed on a silicon substrate. For example, the base substrate 710 may be a silicon semiconductor substrate formed through a complementary metal oxide semiconductor (CMOS) process. The base substrate 710 may include any one of a monocrystalline silicon wafer, a polycrystalline silicon wafer, and/or an amorphous silicon wafer.

The transistor TR located on the base substrate 710 may include a gate electrode GE, a source electrode SE, and a drain electrode DE. The transistor TR may be configured to independently control the red pixel SR, the green pixel SG and the blue pixel SB, which are included in each of the plurality of pixel groups P. A connection electrode CM, conductive lines and conductive pads, which are electrically connected to the transistor TR, may be further located on the base substrate 710. The connection electrode CM, the conductive lines and the conductive pads may include a conductive material, for example, a metal material.

Referring to FIG. 8, the sensor pixel SS may include a photodiode PD. The photodiode PD may sense reflective light reflected from the user's eye 500 and convert the sensed reflective light into an electrical signal. The photodiode PD may include a gate electrode GE for controlling the output of the electrical signal and a drain electrode DE for outputting the electrical signal to a read-out line RL. The photodiode PD may output the electrical signal corresponding to the sensed reflective light through the drain electrode DE in response to a control signal input to the gate electrode GE. The electrical signal of the photodiode PD may be transferred to the processor 470 outside the display panel 510 through the read-out line RL.

The OLED, which includes a first electrode E1, an emission layer EL, and a second electrode E2, may be located on the semiconductor wafer substrate 700.

The first electrodes E1 may be electrically connected to the transistor TR through the connection electrode CM of the semiconductor wafer substrate 700 and at least one contact hole connected thereto. The first electrodes E1 may be anode electrodes for driving the emission layer EL of each of the red pixel SR, the green pixel SG and the blue pixel SB. The first electrodes E1 may be reflective electrodes. For example, the first electrodes E1 may reflect light emitted from the emission layer EL toward a downward direction. The first electrodes E1 may include a metal material having high light reflectance. For example, the first electrodes E1 may include any one of Al, Al/Cu and AI/TIN. As shown in FIG. 8, the first electrodes E1 may not be formed in the sensor pixel SS. That is, the sensor pixel SS may not include the first electrodes E1

The emission layer EL may be located on the first electrodes E1. The emission layer EL may include a single layer or a plurality of stacked structures. The emission layer EL may be configured to emit white light. The white light may be, for example, light in which blue light, green light, and red light are mixed. Alternatively, the white light may be light in which blue light and yellow light are mixed. As shown in FIG. 8, the emission layer EL may not be formed in the sensor pixel SS. That is, the sensor pixel SS may not include the emission layer EL.

The second electrode E2 may be located on the emission layer EL. The second electrode E2 may be a common electrode, for example, a cathode electrode. The second electrode E2 may be a transmissive or transflective electrode. For example, the second electrode E2 may transmit light emitted from the emission layer EL. The second electrode E2 may include a conductive material. For example, the second electrode E2 may include Li, Ca, LiF/Ca, LiF/Al, Al, Mg, BaF, Ba, Ag, Au, Cu, or their compound or mixture, which has a low work function. As shown in FIG. 8, the second electrode E2 may not be formed in the sensor pixel SS. That is, the sensor pixel SS may not include the second electrode E2.

The thin-film encapsulation layer TFE may be located on the OLED. The thin-film encapsulation layer TFE may be configured to encapsulate the emission layer EL so that oxygen or moisture may be prevented from being permeated into the emission layer EL. The thin-film encapsulation layer TFE may be located on an upper surface and sides of the emission layer EL. The thin-film encapsulation layer TFE may include at least one inorganic layer to prevent oxygen or moisture from being permeated into the emission layer EL. In addition, the thin-film encapsulation layer TFE may include at least one organic layer to protect the emission layer EL from particles such as dust. The inorganic layer of the thin-film encapsulation layer TFE may be formed of a multi-layer in which one or more inorganic layers of a silicon nitride layer, a silicon oxynitride layer, a silicon oxide layer, a titanium oxide layer and an aluminum oxide layer are alternately stacked. The organic layer of the thin-film encapsulation layer TFE may be an organic layer such as an acryl resin, an epoxy resin, a phenolic resin, a polyamide resin, or a polyimide resin.

The color filters CF1, CF2 and CF3 may be located on the thin-film encapsulation layer TFE. The color filters CF1, CF2 and CF3 may include a red color filter CF1 (e.g., a first color filter) that transmits red light, a green color filter CF2 (e.g., a second color filter) that transmits green light, and a blue color filter CF3 (e.g., a third color filter) that transmits blue light. The red color filter CF1 may be arranged to correspond to the red pixel SR, thereby transmitting red light among the white light emitted from the emission layer EL of the red pixel SR. The green color filter CF2 may be arranged to correspond to the green pixel SG, thereby transmitting green light among the white light emitted from the emission layer EL of the green pixel SG. The blue color filter CF3 may be arranged to correspond to the blue pixel SB, thereby transmitting blue light among the white light emitted from the emission layer EL of the blue pixel SB. As shown in FIG. 8, the color filters CF1, CF2 and CF3 may not be formed in the sensor pixel SS. That is, the sensor pixel SS may not include the color filters CF1, CF2 and CF3.

FIG. 9 is a plan view illustrating arrangement of a sensor pixel SS included in a pixel group according to some embodiments.

The embodiments illustrated with respect to FIG. 9 may be at least partially similar to the embodiments illustrated with respect to FIG. 6. Hereinafter, only the embodiments illustrated with respect to FIG. 9, which differs from the embodiments illustrated with respect to FIG. 6, will be described. Therefore, features that are not described in FIG. 9 will be replaced with the description of the embodiments illustrated with respect to FIG. 6.

Unlike the embodiments illustrated with respect to FIG. 6, according to the embodiments illustrated with respect to FIG. 9, horizontal and vertical ratios of the blue pixel SB and the sensor pixel SS are different from those of the red pixel SR and the green pixel SG.

Referring to FIG. 9, one pixel group P includes 2*2 sub-areas, and any one of the red pixel SR, the green pixel SG, and composite pixels, in which the blue pixel SB and the sensor pixel SS are arranged to be adjacent to each other, may be located in each of the sub-areas. For example, the red pixel SR may be located in a first row and a first column of each pixel group P, and the green pixel SG may be located in a second row and the first column. The composite pixels in which the blue pixel SB and the sensor pixel SS are arranged to be adjacent to each other may be located in the first row and the second column and a second row and a second column, respectively. The blue pixel SB and the sensor pixel SS may be arranged to be adjacent to each other in a first direction that is a horizontal direction.

Each of the red pixel SR and the green pixel SG may have a horizontal and vertical ratio of 1 to 1. For example, an area of the red pixel SR and an area of the green pixel SG in one pixel group P may be the same as each other, and the red pixel SR and the green pixel SG may have a horizontal and vertical ratio of 1 to 1.

Each of the blue pixel SB and the sensor pixel SS may have a length extended in a second direction, which is a vertical direction, in the second column. For example, the blue pixel SB located in the first row and the blue pixel SB located in the second row may be arranged to be adjacent to each other in the second direction. In addition, the sensor pixel SS located in the first row and the sensor pixel SS located in the second row may be arranged to be adjacent to each other in the second direction.

Therefore, the blue pixel SB and the sensor pixel SS may have a horizontal and vertical ratio of 1/2 to 2.

A horizontal width of the sensor pixel SS may correspond to a half of a horizontal width of the red pixel SR (or the green pixel SG). For example, a vertical width of the sensor pixel SS may correspond to twice of a vertical width of the red pixel SR (or the green pixel SG).

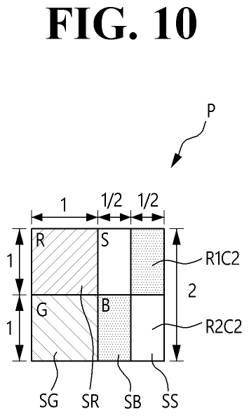

FIG. 10 is a plan view illustrating arrangement of a sensor pixel SS included in a pixel group P according to some embodiments.

The embodiments illustrated with respect to FIG. 10 may be at least partially similar to the embodiments illustrated with respect to FIG. 9. Hereinafter, only the embodiments illustrated with respect to FIG. 10, which differs from the embodiments illustrated with respect to FIG. 9, will be described. Therefore, features that are not described in FIG. 10 will be replaced with the description of the embodiments illustrated with respect to FIG. 9.

Unlike the embodiments illustrated with respect to FIG. 9, according to the embodiments illustrated with respect to FIG. 10, the blue pixel SB and the sensor pixel SS are arranged in a zigzag shape.

Each of the blue pixel SB and the sensor pixel SS may be arranged in a zigzag shape along the second direction, which is the vertical direction, in the second column. For example, the blue pixel SB located in the first row and the sensor pixel SS located in the second row may be arranged to be adjacent to each other in the second direction. In addition, the sensor pixel SS located in the first row and the blue pixel SB located in the second row may be arranged to be adjacent to each other in the second direction.

The blue pixel SB and the sensor pixel SS are arranged to be adjacent to each other in the first direction, which is the horizontal direction, but in a first sub-area R1C2 corresponding to a first row and a second column, the sensor pixel SS may be arranged to be closer to the red pixel SR positioned in the first column than the blue pixel SB. On the other hand, in a second sub-area R2C2 corresponding to the second row and the second column, the blue pixel SB may be arranged to be closer to the green pixel SG positioned in the first column than the sensor pixel SS. For example, in the first row of the pixel group P, the sensor pixel SS may be located between the red pixel SR and the blue pixel SB, and in the second row of the pixel group P, the blue pixel SB may be located between the green pixel SG and the sensor pixel SS.

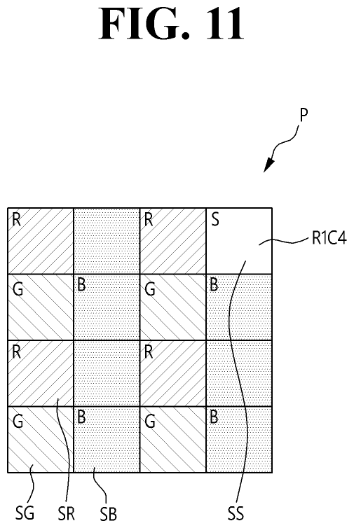

FIG. 11 is a plan view illustrating arrangement of a sensor pixel SS included in a pixel group P according to some embodiments.

The embodiments illustrated with respect to FIG. 11 may be at least partially similar to the embodiments illustrated with respect to FIG. 6. Hereinafter, only the embodiments illustrated with respect to FIG. 11, which differ from the embodiments illustrated with respect to FIG. 6, will be described. Therefore, features that are not described in FIG. 11 will be replaced with the description of the embodiments illustrated with respect to FIG. 6.

According to the embodiments illustrated with respect to FIG. 11, unlike the embodiments illustrated with respect to FIG. 6, one pixel group P includes 4*4 sub-areas, and the sensor pixel SS is located in a sub-area R1C4 positioned at one corner of the 4*4 sub-areas.

The blue pixel SB may be located in the second columns and a portion of the fourth columns of the pixel group P. The blue pixels SB may be located in the fourth columns of the pixel group P except for one sub-area R1C4 corresponding to the first row and the fourth column. For example, the sensor pixel SS may be located in the first row and the fourth column corresponding to the corner of the pixel group P.

The red pixel SR and the green pixel SG may be located in the first and third columns of the pixel group P, and may be alternately arranged along the second direction that is the vertical direction. For example, in the first column of the pixel group P, the red pixel SR may be located in each of the first and third rows, and the green pixel SG may be located in each of the second and fourth rows. In addition, in the third column of the pixel group P, the red pixel SR may be located in each of the first and third rows, and the green pixel SG may be located in each of the second and fourth rows.

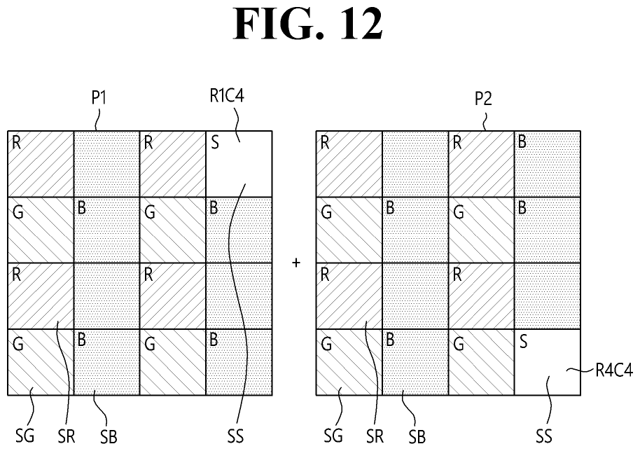

FIG. 12 is a plan view illustrating arrangement of a sensor pixel SS included in a pixel group P according to some embodiments.

The embodiments illustrated with respect to FIG. 12 may be at least partially similar to the embodiments illustrated with respect to FIG. 11. Hereinafter, only the embodiments illustrated with respect to FIG. 12, which differs from the embodiments illustrated with respect to FIG. 11, will be described. Therefore, features that are not described in FIG. 12 will be replaced with the description of the embodiments illustrated with respect to FIG. 11.

Unlike the embodiments illustrated with respect to FIG. 11, in the embodiments illustrated with respect to FIG. 12, the pixel group P has two types, and the two types of pixel groups P are arranged on the display panel 510 in accordance with a designated rule. For example, the display panel 510 may include a hybrid arrangement structure in which a first pixel group P1 and a second pixel group P2 are arranged in accordance with a designated rule.

The pixel group P may include a first pixel group P1 in which pixels are arranged in a first type and a second pixel group P2 in which pixels are arranged in a second type. In the same manner as the embodiments illustrated with respect to FIG. 11, in the first pixel group P1, the sensor pixel SS is located in one sub-area R1C4, which corresponds to the first row and the fourth column, among the 4*4 sub-areas. Unlike the first pixel group P1, in the second pixel group P2, the sensor pixel SS is located in one sub-area R4C4, which corresponds to the fourth row and the fourth column, among the 4*4 sub-areas.

In the display panel 510, the first pixel group P1 and the second pixel group P2 may be arranged in the form of a matrix. Resolution of the first pixel group P1 and resolution of the second pixel group P2 may be the same as each other in the display panel 510. According to some embodiments, the sensor pixel SS in the display panel 510 may be arranged to surround the outside of the display panel 510. For example, first pixel groups P1 in which the sensor pixel SS is located at an upper corner may be arranged on an upper end of the display panel 510, and second pixel groups P2 in which the sensor pixel SS is located at a lower corner may be arranged on a lower end of the display panel 510. Therefore, the sensor pixel SS may be arranged to surround the outside of the display panel 510.

Meanwhile, the position of the sensor pixel SS in each of the first pixel group P1 and the second pixel group P2 is not limited to the shown example. For example, in the first pixel group P1, the sensor pixel SS may be located in the first row and the first column, and in the second pixel group P2, the sensor pixel SS may be located in the fourth row and the first column. Alternatively, in the first pixel group P1, the sensor pixel SS may be located in the fourth row and the first column, and in the second pixel group P2, the sensor pixel SS may be located in the fourth row and the fourth column. Alternatively, in the first pixel group P1, the sensor pixel SS may be located in the first row and the first column, and in the second pixel group P2, the sensor pixel SS may be located in the first row and the fourth column. In addition, the sensor pixel SS may be positioned at any one corner among the 4*4 sub-areas.

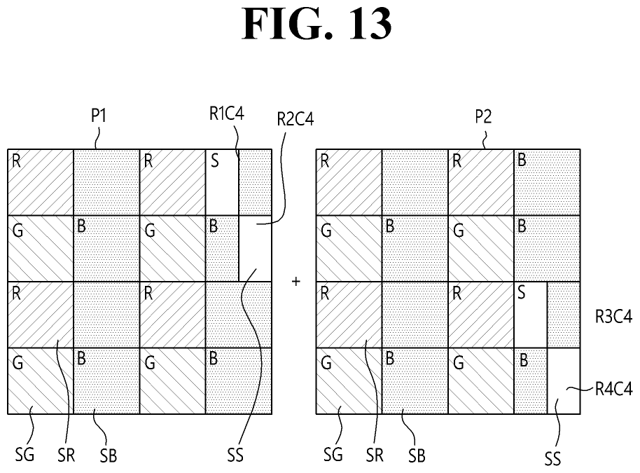

FIG. 13 is a plan view illustrating arrangement of a sensor pixel SS included in a pixel group P according to some embodiments.

The embodiments illustrated with respect to FIG. 13 may be at least partially similar to the embodiments illustrated with respect to FIG. 12. Hereinafter, only the embodiments illustrated with respect to FIG. 13, which differs from the embodiments illustrated with respect to FIG. 12, will be described. Therefore, features that are not described in FIG. 13 will be replaced with the description of the embodiments illustrated with respect to FIG. 12.

Unlike the embodiments illustrated with respect to FIG. 12, according to the embodiments illustrated with respect to FIG. 13, the blue pixel SB and the sensor pixel SS are arranged in a zigzag shape.

The composite pixels in which the blue pixel and the sensor pixel are arranged to be adjacent to each other may be located in one sub-area R1C4 corresponding to the first row and the fourth column in the first pixel group P1. The composite pixels in which the blue pixel and the sensor pixel are arranged to be adjacent to each other may be located in one sub-area R2C4 corresponding to the second row and the fourth column in the first pixel group P1.

The composite pixels in which the blue pixel and the sensor pixel are arranged to be adjacent to each other may be located in one sub-area R3C4 corresponding to the third row and the fourth column in the second pixel group P2. The composite pixels in which the blue pixel and the sensor pixel are arranged to be adjacent to each other may be located in one sub-area R4C4 corresponding to the fourth row and the fourth column in the second pixel group P2.

In each of the first pixel group P1 and the second pixel group P2, each of the blue pixel SB and the sensor pixel SS may be arranged in a zigzag shape along the second direction, which is the vertical direction, in a portion of the fourth columns. For example, in the first pixel group P1, the blue pixel SB located in the first row and the sensor pixel SS located in the second row may be arranged to be adjacent to each other in the second direction. Also, in the first pixel group P1, the sensor pixel SS located in the first row and the blue pixel SB located in the second row may be arranged to be adjacent to each other in the second direction. For example, in the second pixel group P2, the blue pixel SB located in the third row and the sensor pixel SS located in the fourth row may be arranged to be adjacent to each other in the second direction. Also, in the second pixel group P2, the sensor pixel SS located in the third row and the blue pixel SB located in the fourth row may be arranged to be adjacent to each other in the second direction.

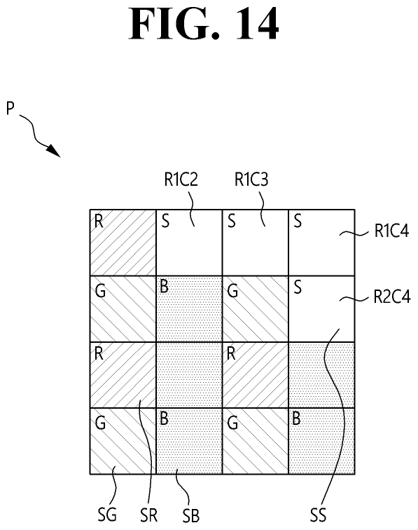

FIG. 14 is a plan view illustrating arrangement of a sensor pixel SS included in a pixel group P according to some embodiments.

The embodiments illustrated with respect to FIG. 14 may be at least partially similar to the embodiments illustrated with respect to FIG. 11. Hereinafter, only the embodiments illustrated with respect to FIG. 14, which differs from the embodiments illustrated with respect to FIG. 11, will be described. Therefore, features that are not described in FIG. 14 will be replaced with the description of the embodiments illustrated with respect to FIG. 11.

Unlike the embodiments illustrated with respect to FIG. 11, in the embodiments illustrated with respect to FIG. 14, the number of sensor pixels SS in the pixel group P is increased to 4.

According to the shown example, one pixel group P includes 4*4 sub-areas, and the sensor pixel SS may be located in four sub-areas. Unlike the embodiments illustrated with respect to FIG. 11, in the embodiments illustrated with respect to FIG. 14, the number of blue pixels SB is reduced, which may be because a change in the number of blue pixels SB is relatively less affected by image quality. That is, in the embodiments illustrated with respect to FIG. 14, a portion of the plurality of blue pixels SB is replaced with the sensor pixel SS, whereby image quality degradation is minimized and at the same time, sensing performance may be improved.

The sensor pixel SS may be arranged to have an alphabet “L”-shape in one pixel group P, and may be positioned at any one corner of the 4*4 sub-areas. For example, the sensor pixel SS may be arranged on the right top of the pixel group, and may have a horizontal and vertical ratio of 3/4 to 2/4. For example, the sensor pixel SS may be located in the sub-area R1C2 corresponding to the first row and the second column, the sub-area R1C3 corresponding to the first row and the fourth column, the sub-area R1C4 corresponding to the first row and the four column, and the sub-area R2C4 corresponding to the second row and the fourth column.

Meanwhile, the position of the sensor pixel SS in the pixel group P is not limited to the shown example. For example, according to some embodiments, in the pixel group P, the sensor pixel SS may be located at a corner of a lower right end, may be located at a corner of a left upper end, or may be located at a corner of a lower left end.

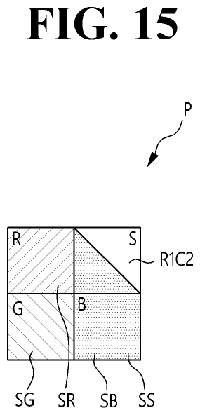

FIG. 15 is a plan view illustrating an arrangement of a sensor pixel SS included in a pixel group P according to some embodiments.

The embodiments illustrated with respect to FIG. 15 may be at least partially similar to the embodiments illustrated with respect to FIG. 6. Hereinafter, only the embodiments illustrated with respect to FIG. 15, which differs from the embodiments illustrated with respect to FIG. 6, will be described. Therefore, features that are not described in FIG. 15 will be replaced with the description of the embodiments illustrated with respect to FIG. 6.

Unlike the embodiments illustrated with respect to FIG. 6, in the embodiments illustrated with respect to FIG. 15, the blue pixel SB and the sensor pixel SS are divided in a diagonal direction in a partial sub-area.

According to the shown example, one pixel group P includes 2*2 sub-areas, and any one of the red pixel SR, the green pixel SG, and the composite pixels, in which the blue pixel SB and the sensor pixel SS are arranged to be adjacent to each other, may be located in each of the sub-areas. For example, in each pixel group P, the red pixel SR may be located in the first row and the first column, the green pixel SG may be located in the second row and the first column, and the blue pixel SB may be located in the second row and the second column. The composite pixels in which the blue pixel SB and the sensor pixel SS are arranged to be adjacent to each other in the diagonal direction may be located in the first row and the second column.

The composite pixels in which the blue pixel SB and the sensor pixel SS are arranged to be adjacent to each other in the diagonal direction may be located in one sub-area R1C2 corresponding to the first row and the second column in the pixel group P, and the sensor pixel SS may be positioned at the corner of the pixel group P. Therefore, the blue pixel SB included in the composite pixels may be positioned to be adjacent to the blue pixel SB located in the second row and the second column.

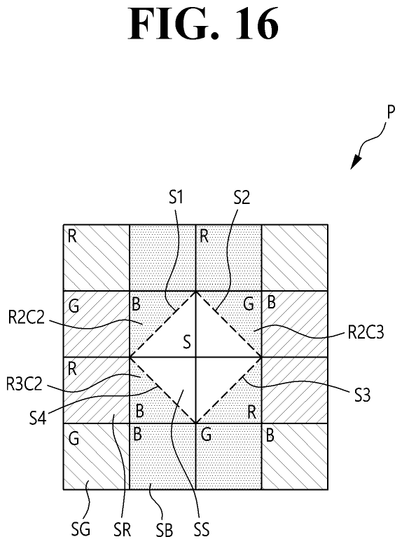

FIG. 16 is a plan view illustrating arrangement of a sensor pixel SS included in a pixel group P according to some embodiments.

The embodiments illustrated with respect to FIG. 16 may be at least partially similar to the embodiments illustrated with respect to FIG. 15. Hereinafter, only the embodiments illustrated with respect to FIG. 16, which differs from the embodiments illustrated with respect to FIG. 15, will be described. Therefore, features that are not described in FIG. 15 will be replaced with the description of the embodiments illustrated with respect to FIG. 15.

Unlike the embodiments illustrated with respect to FIG. 15, in the embodiments illustrated with respect to FIG. 16, one pixel group P includes 4*4 sub-areas, and the composite pixels in which the blue pixel SB and the sensor pixel SS are arranged to be adjacent to each other in the diagonal direction are located in four sub-areas adjacent to the center among the 4*4 sub-areas.

The composite pixels in which the blue pixel SB and the sensor pixel SS are arranged to be adjacent to each other in the diagonal direction may be located in the sub-area R2C2 corresponding to the second row and the second column, a sub-area R2C3 corresponding to the second row and the third column, a sub-area R3C2 corresponding to the third row and the second column, and a sub-area R3C3 corresponding to the third row and the third column. In this case, the blue pixels SB and the sensor pixel SS may be arranged such that four composite pixels are symmetrical based on the center of the pixel group P. For example, in each of the four composite pixels, the blue pixel SB and the sensor pixel SS are adjacent to each other in the diagonal direction, but the sensor pixel SS may be arranged to be closer to the center of the pixel group P than the blue pixel SB. Therefore, the sensor pixels SS may be arranged so that a combination of four sensor pixels SS may have a rhombus shape (or diamond shape) as a whole.

As described above, in the embodiments illustrated with respect to FIG. 16, one pixel group P includes 4*4 sub-areas, and the sensor pixel SS having a rhombus shape (or diamond shape) is located at the center of the pixel group P, and the blue pixel SB, the green pixel SG, and the red pixel SR may be arranged to surround the periphery of the sensor pixel SS.

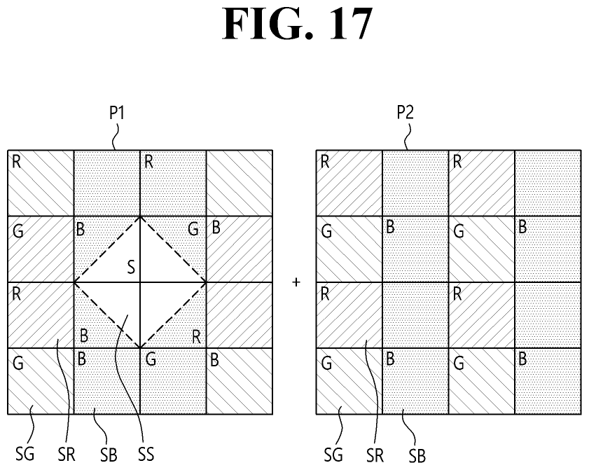

FIG. 17 is a plan view illustrating arrangement of a sensor pixel SS included in a pixel group P according to some embodiments.

The embodiments illustrated with respect to FIG. 17 may be at least partially similar to the embodiments illustrated with respect to FIG. 16. Hereinafter, only the embodiments illustrated with respect to FIG. 17, which differs from the embodiments illustrated with respect to FIG. 16, will be described. Therefore, features that are not described in FIG. 17 will be replaced with the description of the embodiments illustrated with respect to FIG. 16.

Unlike the embodiments illustrated with respect to FIG. 16, in the embodiments illustrated with respect to FIG. 17, the pixel group P has two types, and the two types of pixel groups P are arranged on the display panel 510 in accordance with a designated rule. For example, the display panel 510 may include a hybrid arrangement structure in which a first pixel group P1 and a second pixel group P2 are arranged in accordance with a designated rule.

The pixel group P may include a first pixel group P1 in which pixels are arranged in a first type and a second pixel group P2 in which pixels are arranged in a second type. In the same manner as the embodiments illustrated with respect to FIG. 16, the first pixel group P1 may be arranged so that the sensor pixel SS among the 4*4 sub-areas may have a rhombus shape (or diamond shape) at the center of the pixel group P. Unlike the first pixel group P1, the second pixel group P2 does not include the sensor pixels SS.

In the display panel 510, the first pixel group P1 and the second pixel group P2 may be arranged in the form of a matrix. Resolution of the first pixel group P1 and resolution of the second pixel group P2 may be the same as each other in the display panel 510. For example, the first pixel group P1 and the second pixel group P2 may be alternately arranged. According to some embodiments, the first pixel group P1 including the sensor pixel SS in the display panel 510 may be arranged to surround the outside of the display panel 510, and the second pixel group P2 may be arranged only inside the display panel 510. For example, the first pixel group P1 may be arranged to surround the outside of the plurality of second pixel groups P2. According to some embodiments, the first pixel group P1 in the display panel 510 may be arranged only in fourth corner areas of the display panel 510, and the second pixel group P2 may be located in the other areas.

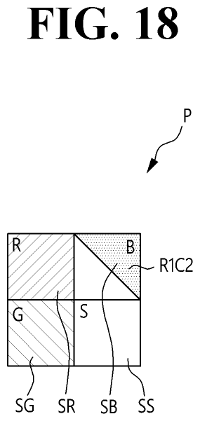

FIG. 18 is a plan view illustrating arrangement of a sensor pixel SS included in a pixel group P according to some embodiments.

The embodiments illustrated and described with respect to FIG. 18 may be at least partially similar to the embodiments illustrated and described with respect to FIG. 15. Hereinafter, only the embodiments illustrated with respect to FIG. 18, which differs from the embodiments illustrated with respect to FIG. 15, will be described. Therefore, features that are not described in FIG. 18 will be replaced with the description of the embodiments illustrated with respect to FIG. 15.

Unlike the embodiments illustrated with respect to FIG. 15, in the embodiments illustrated with respect to FIG. 18, the blue pixel SB is positioned at the corner of the pixel group P.

According to the shown example, one pixel group P includes 2*2 sub-areas, and any one of the red pixel SR, the green pixel SG, and the composite pixels, in which the blue pixel SB and the sensor pixel SS are arranged to be adjacent to each other, may be located in each of the sub-areas. For example, in each pixel group P, the red pixel SR may be located in the first row and the first column, the green pixel SG may be located in the second row and the first column, and the sensor pixel SS may be located in the second row and the second column. The composite pixels in which the blue pixel SB and the sensor pixel SS are arranged to be adjacent to each other in the diagonal direction may be located in one sub-area R1C2 corresponding to the first row and the second column. At this time, the blue pixel SB may be positioned at the corner of the pixel group P. Therefore, the sensor pixel SS included in the composite pixels may be positioned to be adjacent to the sensor pixel SS located in the second row and the second column.

Various embodiments described in the present disclosure should be interpreted as being carried out in combination. For example, the embodiments described in FIGS. 6 and 9 to 18 may be carried out in combination. For example, at least one embodiment selected from the embodiments illustrated with respect to FIG. 6 and the embodiments described in FIGS. 9 to 18 may be carried out in combination.

In concluding the detailed description, those skilled in the art will appreciate that many variations and modifications can be made to the example embodiments without substantially departing from the principles of the present invention. Therefore, the disclosed example embodiments of the invention are used in a generic and descriptive sense only and not for purposes of limitation.

1 what is claimed is:

1. A display device comprising:
a glasses corresponding to a display area of a lens;
a display panel configured to display light;
a reflective member configured to reflect the display light emitted from the display panel in a direction of the glasses; and
a light source unit configured to emit near-infrared light for tracking eyes of a user,
wherein the display panel includes a plurality of pixel groups arranged in a matrix configuration, the pixel groups including a red pixel, a green pixel, a blue pixel and a sensor pixel including a photodiode configured to sense the near-infrared light reflected by the eyes of the user,
one pixel group includes 2*2 sub-areas, and
any one of the red pixel, the green pixel, and composite pixels, in which the blue pixel and the sensor pixel are adjacent to each other, is located in each of the sub-areas.

2. The display device of claim 1, wherein the red pixel and the green pixel have a same area, and each of the red pixel and the green pixel has a horizontal and vertical ratio of 1 to 1, and
each of the blue pixel and the sensor pixel has a horizontal and vertical ratio of 1/2 to 2.

3. The display device of claim 2, wherein, among the 2*2 sub-areas, a blue pixel in a first row and a blue pixel in a second row are adjacent to each other, and a sensor pixel in the first row and a sensor pixel in the second row are adjacent to each other.

4. The display device of claim 2, wherein, among the 2*2 sub-areas, a blue pixel in a first row and a sensor pixel in a second row are adjacent to each other, and a sensor pixel in the first row and a blue pixel in the second row are adjacent to each other.

5. The display device of claim 2, wherein, among the 2*2 sub-areas, the composite pixels in which the blue pixel and the sensor pixel are arranged to be adjacent to each other are in a first row and a first column, and
the blue pixel and the sensor pixel are adjacent to each other in a diagonal direction.

6. The display device of claim 5, wherein the sensor pixel is positioned at a corner of the one pixel group, and
the blue pixel is in a second row and a second column among the 2*2 sub-areas.

7. The display device of claim 5, wherein the blue pixel is positioned at a corner of the one pixel group, and
the sensor pixel is in a second row and a second column among the 2*2 sub-areas.

8. A display device comprising:
a glasses corresponding to a display area of a lens;
a display panel configured to emit display light;
a reflective member configured to reflect the display light emitted from the display panel in a direction of the glasses; and
a light source unit configured to emit near-infrared light for tracking eyes of a user,
wherein the display panel includes a plurality of pixel groups arranged in a matrix configuration, the pixel groups including a red pixel, a green pixel, a blue pixel and a sensor pixel including a photodiode configured to sense the near-infrared light reflected by the eyes of the user,
one pixel group includes 4*4 sub-areas, and
any one of the red pixel, the green pixel, the blue pixel and the sensor pixel is in each of the sub-areas.

9. The display device of claim 8, wherein the sensor pixel is in a sub-area positioned at any one corner of the 4*4 sub-areas, and
any one of the red pixel, the green pixel, and the blue pixel is in the other sub-areas except the sub-area positioned at any one corner.

10. The display device of claim 9, wherein, among the 4*4 sub-areas,
the red pixel and the green pixel are in a first column and a third column, in the first column and the third column, the red pixel and the green pixel are alternately arranged, and
the blue pixel is in a second column and a portion of a fourth column except the sensor pixel.

11. The display device of claim 8, wherein the plurality of pixel groups include a first pixel group and a second pixel group, and the first pixel group and the second pixel group are arranged in accordance with a designated rule,
among the 4*4 sub-areas of the first pixel group, the red pixel and the green pixel are alternately arranged in a first column and a third column, the blue pixel is in a second column and a portion of a fourth column except the sensor pixel, and the sensor pixel is in a first row and the fourth column, and
among the 4*4 sub-areas of the second pixel group, the red pixel and the green pixel are alternately arranged in the first column and the third column, the blue pixel is in the second column and a portion of the fourth column except the sensor pixel, and the sensor pixel is in a fourth row and the fourth column.

12. The display device of claim 11, wherein a resolution of the first pixel group is equal to a resolution of the second pixel group in the display panel.

13. The display device of claim 11, wherein the plurality of pixel groups include a first pixel group and a second pixel group, and the first pixel group and the second pixel group are arranged in accordance with a designated rule,
among the 4*4 sub-areas of the first pixel group, composite pixels in which the blue pixel and the sensor pixel are adjacent to each other in a diagonal direction are located in four sub-areas adjacent to a center of the first pixel group, and
the second pixel group does not include the sensor pixel.

14. The display device of claim 13, wherein, among the 4*4 sub-areas of the first pixel group, the composite pixels are in a second row and a second column, the second row and a third column, a third row and the second column, and the third row and the third column, and the blue pixel and the sensor pixel are arranged such that the composite pixels are symmetrical based on the center of the first pixel group.

15. The display device of claim 14, wherein the sensor pixel in the first pixel group is closer to the center of the first pixel group than the blue pixel, so that a combination of adjacent sensor pixels has a rhombus shape as a whole.

16. The display device of claim 13, wherein a resolution of the first pixel group is equal to a resolution of the second pixel group in the display panel.

17. The display device of claim 16, wherein the first pixel group and the second pixel group are alternately arranged.

18. The display device of claim 16, wherein the first pixel group surrounds an outside of the display panel, and the second pixel group is inside the display panel.

19. The display device of claim 16, wherein the first pixel group is only in four corner areas of the display panel, and
the second pixel group is in the other area except the four corner areas.

20. The display device of claim 8, wherein the display panel includes a semiconductor wafer substrate and an OLED on the semiconductor wafer substrate.
